(19) United States
(12) Patent Application Publication
(10) Pub. No.: US 2014/0027808 A1
(43) Pub. Date: Jan. 30, 2014

(54) LATERAL CARRIER INJECTION INFRARED LIGHT EMITTING DIODE STRUCTURE, METHOD AND APPLICATIONS

(71) Applicant: UNIVERSITY OF ROCHESTER, ROCHESTER, NY (US)

(72) Inventors: Karl S. Ni, Rochester, NY (US); Halina Krzyzanowska, Rochester, NY (US); Yijing Fu, Bellevue, WA (US); Philippe M. Fauchet, Pittsford, NY (US)

(73) Assignee: UNIVERSITY OF ROCHESTER, ROCHESTER, NY (US)

(21) Appl. No.: 13/950,709

(22) Filed: Jul. 25, 2013

Related U.S. Application Data
(60) Provisional application No. 61/675,958, filed on Jul. 26, 2012.

(51) Int. Cl. H01L 33/00

(52) U.S. Cl. CPC H01L 33/0012; H01L 33/0054; Y10S 977/814; Y10S 977/89; Y10S 977/95; B82Y 40/00
USPC 257/99; 438/22; 438/46; 977/814; 977/890; 977/950

(57) ABSTRACT

A Si-based light emitting diode structure and a method for fabricating the Si-based light emitting diode structure are each predicated upon a multilayer material layer that comprises alternating, interposed and laminated sub-layers of: (1) a group IV nanocrystal material; and (2) an erbium or neodymium doped dielectric material. The light emitting diode structure is preferably laterally actuated to provide both efficient photoluminescence and electroluminescence. The group IV nanocrystal material may comprise a silicon nanocrystal material and the doped dielectric material may comprise an erbium doped silicon oxide material.

### CROSS-REFERENCE TO RELATED APPLICATION

This application is related to, and derives priority from, application Ser. No. 61/675,958, filed 26 Jul. 2012 and titled Light Emitting Diode Apparatus, Method, and Applications, the content of which is incorporated herein fully by reference.

### STATEMENT OF GOVERNMENT INTEREST

The research that lead to the embodiments as described herein, and the invention as claimed herein, was funded by the United States AFOSR under MURI program with sub-award number 05710002027, award FA 9550-06-1-0470. The United States Government has rights in the invention as claimed herein.

### BACKGROUND

1. Field of the Invention

Embodiments relate generally to light emitting diode structures and related methods. More particularly, embodiments relate to enhanced performance light emitting diode structures and related methods.

2. Description of the Related Art

Although efficient light emitting sources predicated upon silicon based nanostructures may not yet have been demonstrated, such silicon nanostructure based light sources are clearly desirable. Such silicon nanostructure based light sources are desirable insofar as they may presumably be fabricated using otherwise conventional silicon nanostructure based processing fabrication tooling.

Since such silicon nanostructure based light sources are in particular very attractive in optical signal processing applications and related applications, desirable are silicon nanostructure based light sources, methods for fabrication thereof and methods for use thereof.

### SUMMARY

Embodiments include a silicon nanostructure based infrared light emitting diode structure and a method for fabricating the silicon nanostructure based infrared light emitting diode structure. The particular silicon nanostructure based light emitting diode structure in accordance with the embodiments utilizes a lateral p-i-n diode carrier injection (i.e., relative to a plane of a substrate over which is located and fabricated the silicon nanostructure), rather than a vertical p-i-n diode carrier injection. The particular silicon nanostructure based light emitting diode structure in accordance with the embodiments also includes, located over a Si substrate and a thick dielectric layer that is generally transparent to a light emitting diode emitted wavelength and also insulating electrically, a multilayer material layer comprising alternating, interposed and laminated sub-layers of: (1) a group IV nanocrystalline material; and (2) a dielectric material doped with at least one of erbium and neodymium. To define a waveguide mode, the multilayer material layer structure in accordance with the embodiments is further covered by a dielectric capping layer. However, other structural designs may also alternatively be proposed to localize a waveguide mode within a silicon nanostructure based infrared light emitting diode structure in accordance with the embodiments.

In a particular embodiment: (1) the group IV nanocrystal material may comprise a nanocrystalline silicon material (i.e., nc-Si); and (2) the dielectric material may comprise an erbium doped silicon oxide material (i.e., Er—SiOₓ).

Within the context of the embodiments as disclosed and the invention as claimed, a “sub-layer” with respect to a “multilayer material layer” is intended as comprising an individual one of: (1) a group IV nanocrystalline material; and (2) a dielectric material (as described above) which alternates with, is interposed between and laminated to an individual one of the other of: (1) the group IV nanocrystalline material; and (2) the dielectric material (as described above).

Within the context of the embodiments as disclosed and the invention as claimed, use of the terminology “over” for a particular layer or structure with respect to an additional layer or structure is intended to describe a relative vertical location of the particular layer or structure with respect to the additional layer or structure, absent necessary contact of the particular layer or structure with respect to the additional layer or structure. In contrast, use of the terminology “upon” for a particular layer or structure with respect to an additional layer or structure is intended to describe the same relative vertical location of the particular layer or structure with respect to the additional layer or structure, but with necessary contact of the particular layer or structure with respect to the additional layer or structure.

Within the context of the embodiments as disclosed and the invention as claimed, when materials of stoichiometric composition are described within an operational component, layer or structure also intended are related materials of non-stoichiometric composition.

Within the context of the embodiments as disclosed and the invention as claimed, a “structure” is generally intended as a physical assemblage of layers of described materials composition and location, while a “device” is generally intended as a “structure” that is electrically energized and optically active.

A particular light emitting diode structure in accordance with the embodiments includes a substrate (i.e., often but not exclusively a Si substrate, and including a thermal SiO₂ layer to insulate a multilayer material layer structure in accordance with the embodiments from the Si substrate, and simultaneously also transparent to a wavelength emitted from the multilayer material layer structure). This particular light emitting diode structure also includes a multilayer material layer located over the substrate (and the optional additional insulating layer). The multilayer material layer includes: (1) a plurality of group IV nanocrystal material sub-layers; and (2) a plurality of dielectric material sub-layers doped with at least one of erbium and neodymium, and alternating with, interposed between and laminated to the plurality of group IV nanocrystal material sub-layers. The multilayer material layer structure is doped (i.e., typically but not necessarily exclusively by means of ion implantation) to provide a p-i-n diode. This particular light emitting diode structure also includes at least two electrodes, one edge coupled to each of a p region and an n region within the p-i-n diode. As well, this particular light emitting diode structure may also include a dielectric capping layer over the multilayer material layer to define a waveguide mode within the multilayer material layer.

A particular method for fabricating a light emitting diode structure in accordance with the embodiments includes forming over a substrate a multilayer material layer including: (1) a plurality of group IV nanocrystal material sub-layers; and (2) a plurality of dielectric material sub-layers doped with at least one of erbium and neodymium, and alternating with, interposed between and laminated to the plurality of group IV nanocrystal material sub-layers. This particular method also includes doping the multilayer material layer to form a p-i-n diode. This particular method also includes forming over the substrate at least two electrodes, one coupled to each of a p region and an n region within the p-i-n diode.

### BRIEF DESCRIPTION OF THE DRAWINGS

The objects, features and advantages of the embodiments are understood within the context of the Detailed Description of the Non-Limiting Embodiments, as set forth below. The Detailed Description of the Non-Limiting Embodiments is understood within the context of the accompanying drawings, that form a material part of this disclosure, wherein:

FIG. 1a shows a schematic perspective-view diagram of a silicon based light emitting diode nanostructure in accordance with the embodiments. The main elements are: Si substrate, a thermal SiO₂ layer to insulate the multilayer material layer from the substrate and simultaneously provide a structure transparent to a wavelength emitted from the multilayer material layer structure, the multilayer material layer structure, and an insulating SiO₂ capping layer to define a waveguide mode formed in the multilayer material layer structure. FIG. 1a also illustrates a lateral carrier injection in accordance with the embodiments. Electrons and holes are directly injected into the nc-Si layers. A current I flows from a positive electrode (p) to a negative electrode (n) through the intrisic (i) Si regions, which contain silicon nanocrystals. The injected charges excite the Er ions located in the oxide dielectric layers. Light generated in the multilayer material layer device structure is emitted from a facet of the device structure. FIG. 1b shows a cross-section SEM image of a structure from which is formed the device. A Ti electrode, an Er doped SiO₂/nc-Si multilayer material layer structure, and a thermal oxide layer are presented and shown.

FIG. 2a shows a schematic top-view diagram of a final device structure. p and n regions, and a waveguide coupler, are illustrated. FIG. 2b shows an image of the final device structure from an optical microscope. The electrodes and waveguide coupler are illustrated and depicted. FIG. 2c shows a schematic cross-sectional diagram of the device structure in accordance with an alternative embodiment. It consists of one doped p region and one doped n region, each with a V-shape Ti electrode, Er doped SiO₂/nc-Si multilayer material layer, a thermal oxide insulating layer formed on a Si substrate, and a SiO₂ capping layer on the top of the multilayer. FIG. 2d shows a cross-section SEM image of the device structure. FIG. 2e shows a magnification of the waveguide region with estimated a height and a width of the SiO₂ capping layer.

FIG. 3 shows a schematic diagram of an apparatus for measuring electroluminescence from a silicon nanostructure based light emitting diode device in accordance with the embodiments under simultaneous electrical and optical pumping.

FIG. 4a shows I-V characteristics from Er doped SiO₂/nc-Si multilayer material layers with 5 nm layers and a 50 μm of electrode spacing (black squares) and 15 nm layers and a 200 μm of electrode spacing (red (i.e., lighter gray shade) circles and a 50 μm of electrode spacing (red (i.e., lighter gray shade) open squares): on a linear scale in forward and reverse bias. The total thicknesses of the Si and SiO₂ layers, as well as Er concentration, are the same in both cases. FIG. 4b shows current-voltage curve obtained from the device (see the sequence of diagrams in FIG. 2). Here, the voltage threshold is estimated as 1.5 V for the device with a 30 μm of electrode spacing. The saturation of the current value at 0.06 A for a voltage above of 20 V is an artifact due to a limitation of the instrument performing the measurement. All I-V curves present good rectifying behavior from the p-i-n devices and also exhibit efficient electroluminescence under forward bias.

FIG. 5a shows electroluminescence spectra from an Er doped SiO₂/nc-Si multilayer with 15 nm layer thickness and electrode spacing of 40 μm under different applied forward voltages. A photoluminescence spectrum is shown for comparison. FIG. 5b shows electroluminescence intensity vs. current density from identical p-i-n light emitting diode structures with different electrode spacing.

FIG. 6 shows electroluminescence spectra of light emitting diode devices in accordance with the embodiments as a function of current density, where the multilayer material layers within the light emitting diode structures that provide the light emitting diode devices are deposited with and without a substrate bias. The EL spectra from the devices with a 10 μm of electrode spacing and different layer thicknesses reveal that the lowest current density threshold is obtained for a structure with a 15 nm thickness of a Si layer. This thickness value was used to design a waveguide coupling light emitting diode (see FIG. 2).

FIG. 7 shows electroluminescence spectra of light emitting diode devices in accordance with the embodiments as a function of logarithm of voltage, where the multilayer material layers within the light emitting diode structures that provide the light emitting diode devices are deposited with and without a substrate bias. The lowest voltage threshold for EL was achieved for samples where the substrate bias was applied.

FIG. 8a to FIG. 8d shows a series of schematic cross-sectional diagrams illustrating the results of progressive stages in fabricating a light emitting diode structure in accordance with another additional embodiment.

FIG. 9 shows comparative current voltage characteristics of silicon nanostructure based light emitting diode structures in accordance with the embodiment of FIG. 1a and the additional embodiment of FIG. 8a to FIG. 8d.

### DETAILED DESCRIPTION OF THE NON-LIMITING EMBODIMENTS

### 1. General Considerations

While the embodiments that follow describe most particularly results of studies of Er doped SiO₂/nc-Si multilayer material layer that show within a light emitting diode device a strong electroluminescence (EL) under lateral carrier injection in forward bias, the embodiments are not intended to be so specifically limited. Rather, the embodiments are intended to include alternative doped dielectric/nc-group IV multilayer material layer compositions within the context of photoluminescence improvements and electroluminescence improvements. Thus, included within candidate multilayer material layer compositions for use within a light emitting diode structure or device in accordance with the embodiments are: (1) at least one lanthanide element dopant selected from the group consisting of erbium and neodymium, within any of several dielectric materials (i.e., silicon containing dielectric materials and alternative dielectric materials), including but not limited to silicon oxide, silicon nitride and silicon oxynitride or other dielectric materials like e.g., Al₂O₃ or stoichiometric erbium silicates (Er₂SiO₅ or Er₂Si₂O₇), and (2) any of several group IV nanocrystal semiconductor materials, including but not limited to silicon, germanium, silicon-germanium alloy, silicon-carbon alloy, germanium-carbon alloy and silicon-germanium-carbon alloy group IV semiconductor materials.

Within a multilayer material layer in accordance with the embodiments, a thickness of a dielectric material sub-layer ranges from about 2 to about 50 nanometers, while a thickness of a group IV material sub-layer ranges from about 2 to about 50 nanometers, to provide a total thickness of a multilayer material layer from about 200 to about 1000 nanometers. As well, erbium and/or neodymium dopant concentrations within a doped silicon containing dielectric material sub-layer ranges from about 0.1 to about 2 atomic percent.

In addition, doping levels for forming a lateral p-i-n diode structure within a multilayer material layer in accordance with the embodiments range from about 10¹⁸ to about 10²² dopant atoms per cubic centimeter for a p dopant and from about 10¹⁸ to about 10²² dopant atoms per cubic centimeter for an n dopant. As will be discussed in further detail below, specific non-limiting ion implantation conditions may be used to secure the foregoing volume concentrations of a p dopant and an n dopant within a multilayer material layer in accordance with the embodiments.

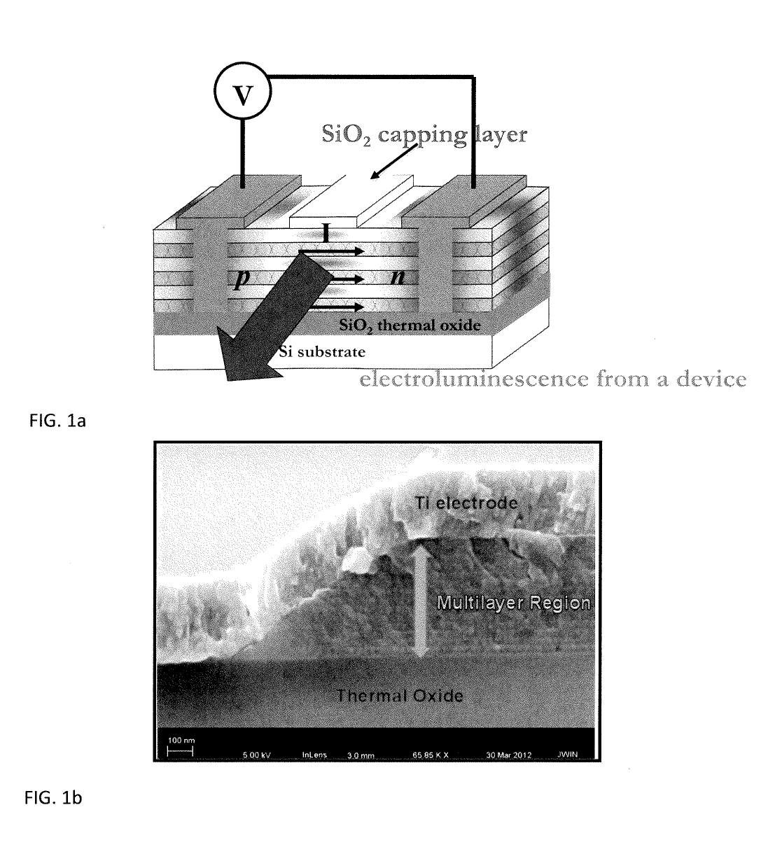

A particular schematic perspective view diagram illustrating a lateral charge injection p-i-n light emitting diode structure in accordance with the embodiments is illustrated in FIG. 1a. FIG. 1a shows a silicon substrate, a thermal SiO₂ layer to insulate a multilayer material layer structure from the silicon substrate, the multilayer material layer structure, and an insulating SiO₂ capping layer to define a waveguide mode formed in the multilayer material layer. FIG. 1a also illustrates the p, i and n regions of the multilayer material layer to provide a lateral p-i-n diode. FIG. 1a also shows a voltage source V that is attached to the two electrodes that in-turn contact and are edge coupled with the p and n doped regions of the lateral p-i-n diode. As described above, shown in FIG. 1a is a waveguide capping layer located and formed upon the multilayer material layer and laterally interposed between the electrodes. The waveguide is used for defining optical output from the multilayer material layer to be perpendicular to the direction of current travel through the group IV nanocrystal material sub-layers (i.e., emitted optical output is from the exposed vertical face of the multilayer material layer interposed between the two electrodes as illustrated in FIG. 1a).

### 2. Er Doped SiO₂/nc-Si Multilayer Material Layers

The embodiments more specifically provide results of studies of Er doped SiO₂/nc-Si multilayer material layers that show: (1) strong photoluminescence (PL) under erbium in SiO₂ matrix off-resonant optical pumping; and (2) strong electroluminescence (EL) under lateral carrier injection in forward bias. Carriers injected in the intrinsic region of the lateral p-i-n diode structure excite the Er ions located in the SiO₂ layers. A major advantage of the embodied method and structure in accordance with the embodiments compared with vertical carrier injection is that transport is much easier and that the Er—Si distance is very well defined. Er doped SiO₂/nc-Si multilayer material layers may also serve as waveguides to achieve amplification and eventually lasing, and minimize losses due to free carrier absorption because they act as horizontal multislot waveguides that confine an optical field into the SiO₂ layers, away from the Si layers where the free carriers are injected. Since optical pumping of Er-doped silica waveguides sensitized by nc-Si has already produced net optical gain, the embodied ordered structures that are less susceptible to free carrier absorption losses should be able to achieve significant optical gain.

2.1 Fabrication of Electroluminescent Device

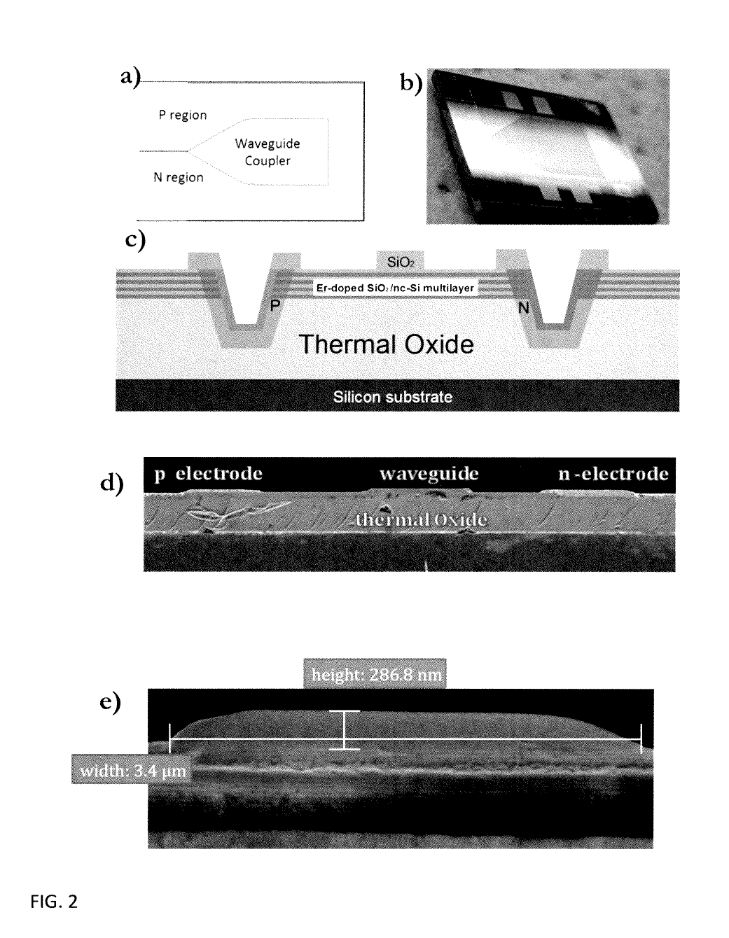

Multilayer material layer fabrication for electroluminescence studies was the same as generally described above except that deposition was on 5 μm thick thermally grown SiO₂ on Si (100) wafers. Er doped SiO₂/nc-Si multilayer structures were deposited using radio frequency magnetron sputtering. However, any other deposition technique with a nanometer resolution of thickness (e.g. molecular beam epitaxy (MBE)) may be used to produce similar multilayer structures. In this particular case, the following deposition rates were estimated: 0.0315 nm/s and 0.0383 nm/s for SiO₂ and Si, respectively. Er doping SiO₂ layer is achieved by co-sputtering Er with a pure Er metal target simultaneously with SiO₂, while the Er concentration is controlled by the plasma power applied onto an Er target. A plasma power of 40 W was applied. Multilayers are fabricated by alternating deposition of multiple layers of nm-thin a-Si and Er-doped SiO₂ thin films. Subsequently, deposited samples are thermal annealed in a furnace tube at 1050 C for 1 hour, to form the silicon nanostructure and to activate the Er atoms. FIG. 2c shows a schematic perspective view diagram of an embodied device. Reactive ion etching was used to etch trenches into which were fitted the electrodes for p and n contact within p-i-n diodes. Sequential ion implantation of P and B with dose 5*10¹⁵ at./cm² and energies 90 keV/120 keV, respectively was used to form a lateral p-i-n structure with the intrinsic region forming the waveguide core. Subsequently, Ti films were deposited using electron beam evaporation to form the electrodes. The multilayer material layers then underwent a rapid thermal anneal at 600° C. for 45 seconds, followed by 750° C. for 45 seconds to form titanium silicide and to activate the dopants. Electrons and holes were injected in the intrinsic region of the nc-Si layers from which they can excite the Er ions in the SiO₂ layers. Samples with various electrode spacings and sizes were prepared to optimize lateral carrier flow. Representative cross-section SEM images of a multilayer device with electrodes spacing of 30 μm is shown in FIGS. 2d,e.

### 3. Results

3.1 Current-Voltage Characteristics and Electroluminescence Results

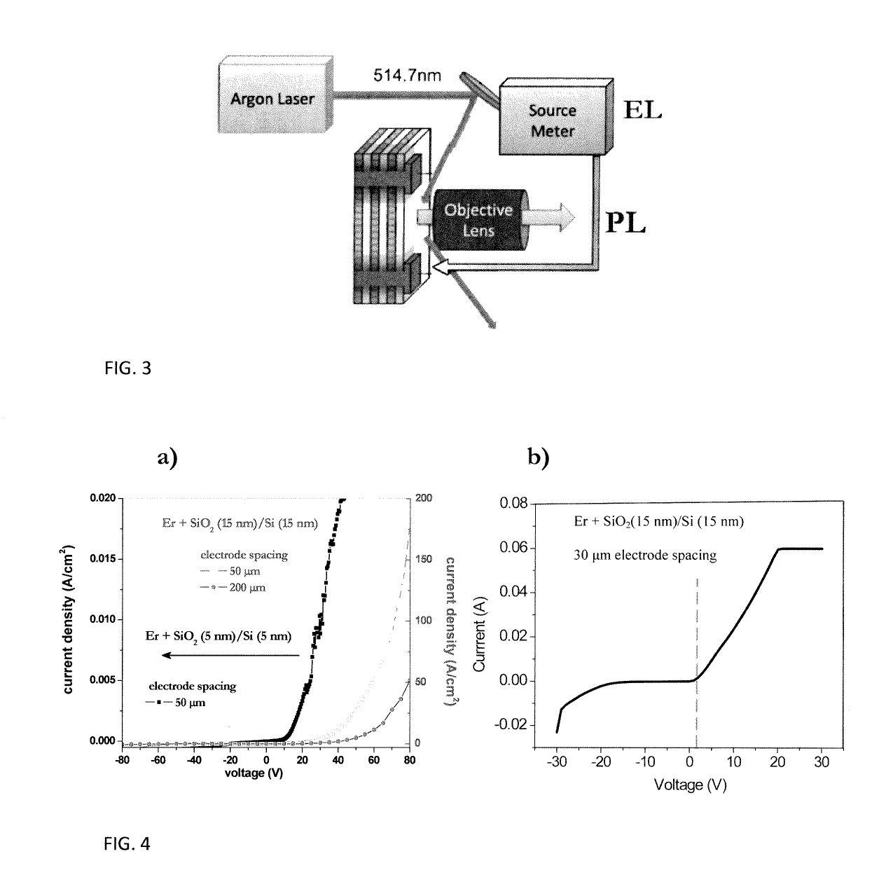

Most studies on electrical pumping use vertical carrier injection where charge flow is limited by an oxide dielectric layer. The embodied approach instead makes use of a lateral p-i-n junction embedded into a multilayer material layer. To verify that lateral electrical injection had taken place, current-voltage measurements were performed. The I-V curves for multilayer material layer with different layer thicknesses, electrodes spacings, and widths are presented in FIG. 4. Simultaneous electrical and optical pumping may be effected using an apparatus as illustrated in FIG. 3. For all samples the leakage current density in reverse bias is low (about 0.5 A/cm² at −40V) and the I-V curves exhibit good rectifying characteristics, as illustrated in FIG. 4a. For a fixed (15 nm) Si and Er:SiO₂ layer thickness, the turn-on voltage shifts to lower values with decreasing electrode spacing. For comparison, a multilayer material layer with the same electrode spacing (50 μm) and width (40 μm) but with Si and Er:SiO₂ layers that were 5 nm thick, was also measured. In this sample, the current is lower by several orders of magnitude, indicating that transport is more difficult in thinner nanocrystalline layers. FIG. 4b shows current-voltage curve obtained from the device (see the sequence of pictures in FIG. 2). Here, the low voltage (1.5V) threshold was achieved for the structure with the electrode spacing of 30 μm. The saturation of the current value at 0.06 A for a voltage above of 20 V is an artifact due to a limitation of the instrument performing the measurement. All I-V curves present in FIG. 4 reveal good rectifying behavior from the p-i-n devices and also exhibit efficient electroluminescence under forward bias.

In order to confirm that electrons and holes are actually transferred to the Er ions, the infrared electroluminescence spectrum from multilayer material layers was measured. Typical EL spectra taken under forward bias for a structure with 15 nm thick Si and Er:SiO₂ layers are shown in FIG. 5a. The PL and EL spectra are identical and the EL intensity strongly depends on applied voltage. The applied voltage required to achieve measurable EL is high because the width of the intrinsic region is large. FIG. 5b shows the EL as a function of the current density for three structures. The threshold current density for achieving measurable EL appears to be the same for the three structures. The injected carrier concentration in EL experiments is lower than the injected carrier concentration at high pump intensity. Therefore, concentration quenching and up conversion are ruled out. The multilayer material layers contain a number of interface states, localized states in the Si nanostructures, and defects in the Er doped SiO₂ layer. Optically injected carriers can be trapped by these states and then escape by thermally-assisted processes, similar with multiple trapping in disordered materials. Carrier trapping also affects the EL intensity.

In PL experiment, energy is transferred from Si nanostructures to Er via the Forster and/or Dexter processes. In EL studies, the detailed mechanisms for excitation of the Er ions under forward bias are not yet established. The injected carrier concentration in EL experiments is lower than the injected carrier concentration at high pump intensity. Therefore, concentration quenching and up conversion processes may be ruled out. Sequential transfer of negative and positive charges may occur.

### 4. Additional Embodiments

Considered as an additional embodiment when fabricating a multilayer material layer in accordance with the embodiments is the addition of a substrate bias when fabricating over a substrate a multilayer material layer in accordance with the embodiments. Such a substrate bias may be in a range from about 0 W and 0 volts to about 30 W and 100 volts.

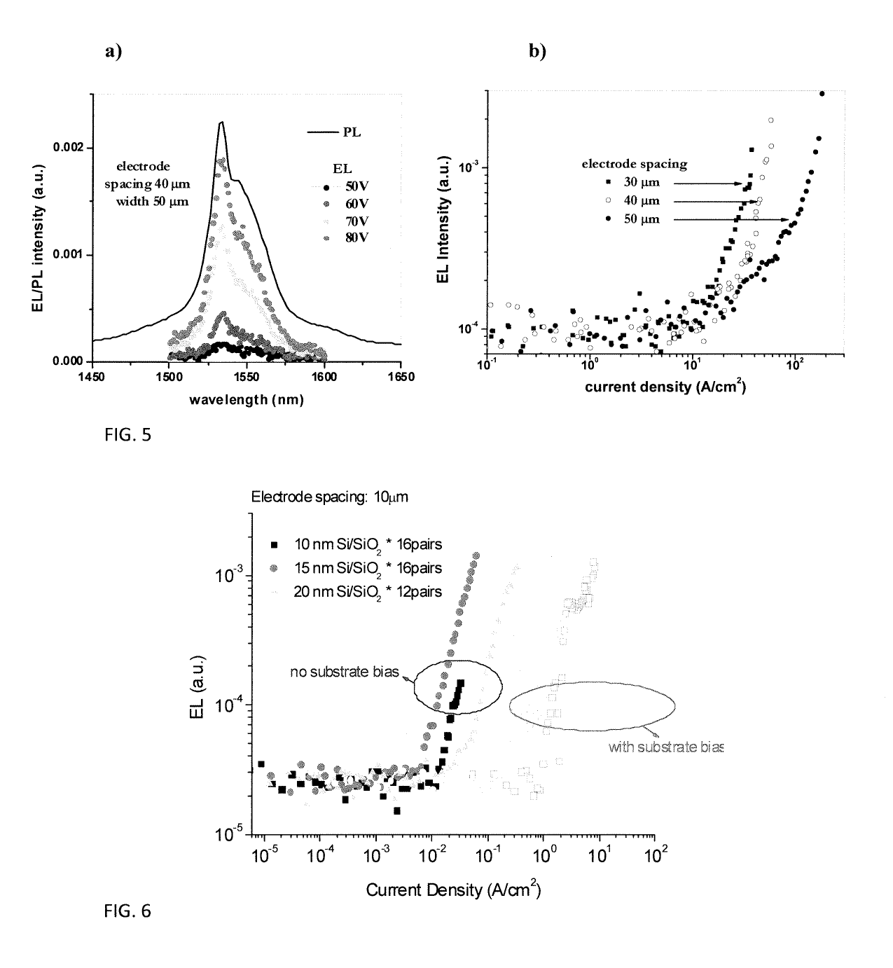

FIG. 6 shows current density electroluminescence characteristics of light emitting diode structures fabricated in accordance with the embodiments both with and without the foregoing substrate bias. As can be seen from the graphical data of FIG. 6, a substrate bias when fabricating a multilayer material layer provides a light emitting diode device fabricated from the multilayer material layer with less susceptibility (i.e., a higher current density threshold) for light emission.

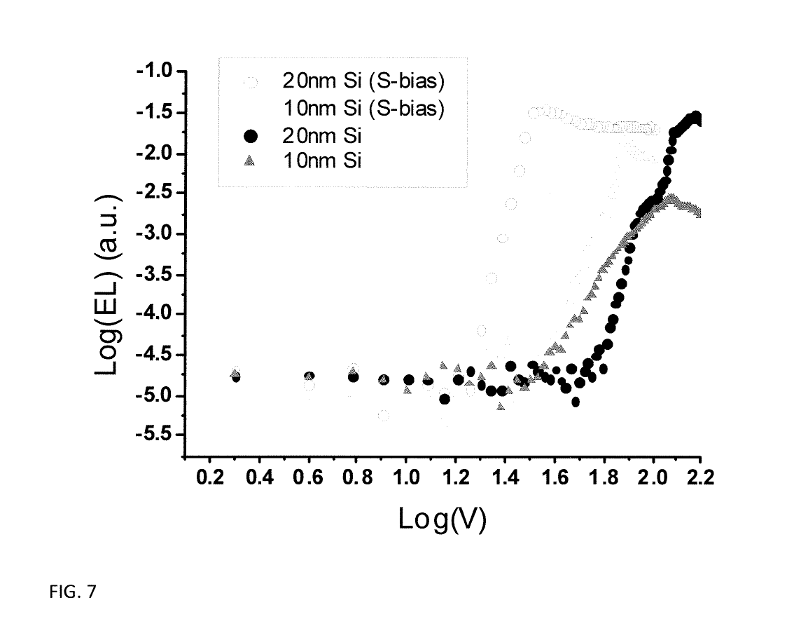

FIG. 7 shows threshold voltage electroluminescence characteristics of light emitting diode structures fabricated in accordance with the embodiments also both with and without the foregoing substrate bias. As can be seen from the graphical data of FIG.7, a substrate bias when fabricating a multilayer material layer provides a light emitting diode device fabricated from the multilayer with a lower voltage threshold for EL.

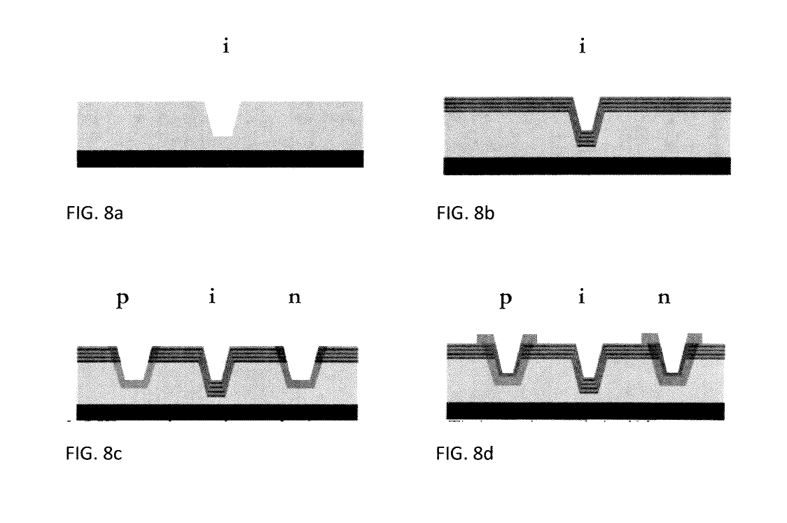

In comparison with FIGS. 1a and b, FIG. 8a to FIG. 8d shows a series of schematic diagrams and SEM cross-sectional images illustrating the results of progressive stages in fabricating a light emitting diode structure in accordance with another additional embodiment. In accordance with FIG. 8a, this particular other additional embodiment starts by first forming a trench within a dielectric layer (i.e., upper lying layer) located and formed upon a substrate such as but not limited to a semiconductor substrate. Such a trench may have a linewidth dimension from about 500 to about 10000 nanometers and a length from about 100 to about 10000 microns as well as a depth within the dielectric layer from about 0.1 to about 4 microns. Such a trench may be formed using reactive ion etch methods as are otherwise generally conventional, and such a trench may have a sidewall slope from about 0 to about 60 degrees versus a normal to the substrate surface.

As is illustrated within FIG. 8b a multilayer material layer otherwise in accordance with FIG. 1a is located and formed upon the structure as is illustrated within FIG. 8a, and in particular conformally into, but not filling, the trench.

FIG. 8c shows the results of forming additional trenches through the multilayer material layer and also into the dielectric layer. As well, FIG. 8c also shows the results of ion implantation into each of the newly excavated trench regions a p doped region and an n doped region to form a p-i-n diode in accordance with the foregoing embodiments, but where the p-i-n diode has a topography due to the original trench as illustrated in FIG. 8a.

Finally, FIG. 8d shows the results of locating and forming electrodes into the peripheral trenches to provide electrical contact to the p-i-n diode.

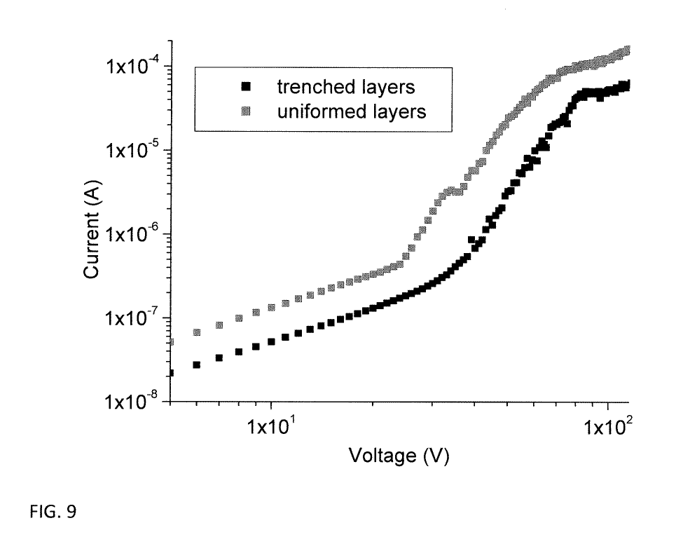

FIG. 9 shows a graph of current-voltage characteristics of a p-i-n diode in accordance with the embodiments as a function of whether the p-i-n diode is planar, or alternatively topographic as a result of being formed conformally into a trench. As is illustrated in FIG. 9, planar p-i-n diodes (i.e., upper data trace) generally have superior response performance. Generally, it is observed that p-i-n diodes located and formed upon a planar substrate have a higher carrier injection efficiency and a lower electroluminescence efficiency, while p-i-n diodes located and formed upon topographic trenched surfaces have a lower carrier injection efficiency and a higher electroluminescence efficiency.

### 5. Conclusions

The embodiments illustrate that Er doped SiO₂/Si multilayers may be used to achieve strong infrared photoluminescence and electroluminescence at the standard telecommunication wavelength of 1535 nm. Efficient photoluminescence was achieved because the Er ions located in thin SiO₂ layers could be excited via energy transfer from nc-Si layers. Lateral carrier injection and electroluminescence in a lateral p-i-n configuration under forward bias are reported as a function of electrode spacing and layer thickness from precisely controlled multilayer material layer structures. These results are promising for the development of an on-chip silicon light source.

All references, including publications, patent applications, and patents cited herein are hereby incorporated by reference in their entireties to the same extent as if each reference was individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it was individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

What is claimed is:

1. A nanostructure comprising:
a substrate;
a multilayer material layer with located over the substrate, the multilayer material layer comprising:
a plurality of group IV nanocrystal material sub-layers; and
a plurality of doped dielectric material sub-layers doped with at least one of erbium and neodymium, and alternating with, interposed between and laminated to the plurality of group IV nanocrystal material sub-layers, where the multilayer material layer is doped to provide a p-i-n diode.

2. The nanostructure of claim 1 further comprising:
at least two electrodes, one coupled to each of a p region and an n region within the p-i-n diode;
an additional dielectric isolation layer located interposed between the substrate and the multilayer material layer; and
an additional dielectric capping layer located on the top of the multilayer material layer to define a waveguide mode in the multilayer material layer.

3. The nanostructure of claim 2 wherein:
the multilayer material layer is located over and coplanar with the substrate;
the multilayer material layer is doped through its thickness to provide the p region and the n region supported by an i-regime, where the waveguide mode resides;
the p-i-n diode is a lateral planar p-i-n diode; and
each of the at least two electrodes is coupled to an edge of the multilayer material layer.

4. The nanostructure of claim 2 wherein:
the multilayer material layer is located over and topographic with respect to the substrate;
the multilayer material layer is doped through its thickness to provide the p region and the n region supported by an i-regime, where the waveguide mode resides;
the p-i-n diode is a lateral topographic p-i-n diode; and
each of the at least two electrodes is coupled to an edge of the multilayer material layer.

5. The nanostructure of claim 1 wherein the plurality of group IV nanocrystal material layers comprises a nanocrystal material selected from the group consisting of silicon, germanium, silicon-germanium alloy, silicon-carbon alloy, germanium carbon alloy and silicon-germanium-carbon alloy nanocrystal materials.

6. The nanostructure of claim 1 wherein the plurality of doped dielectric material sub-layers comprises at least one of:
a silicon containing dielectric material selected from the group consisting of silicon oxide, silicon nitride and silicon oxynitride dielectric materials; and
an aluminum containing dielectric material.

7. The nanostructure of claim 1 wherein each of the plurality of group IV nanocrystal material sub-layers has a thickness from about 2 to about 50 nanometers.

8. The nanostructure of claim 1 wherein each of the plurality of doped silicon containing dielectric material sub-layers has a thickness from about 2 to about 50 nanometers.

9. The nanostructure of claim 1 wherein the multilayer material layer comprises a total thickness from about 200 to about 1000 nanometers.

10. The nanostructure of claim 1 wherein:
the group IV nanocrystal material sub-layers comprise a silicon nanocrystal material; and
the doped silicon containing dielectric material sub-layers comprise an erbium doped silicon oxide material.

11. A nanostructure comprising:
a substrate;
a multilayer material layer located over the substrate, the multilayer material layer comprising:
a plurality of silicon nanocrystal material sub-layers; and
a plurality of erbium doped silicon oxide dielectric material sub-layers alternating, interposed and laminated with the plurality of silicon nanocrystal material sub-layers, where two laterally separated regions of the multilayer material layer are doped to provide a p-i-n diode; and
at least two electrodes, one edge coupled to each of a p region and an n region within the p-i-n diode.

12. The nanostructure of claim 11 wherein the p-i-n diode comprises a lateral planar p-i-n diode.

13. The nanostructure of claim 11 wherein the p-i-n diode comprises a lateral topographic p-i-n diode.

14. A method for fabricating a nanostructure comprising:
forming over a substrate a multilayer material layer comprising:
a plurality of group IV nanocrystal material sub-layers; and
a plurality of dielectric material sub-layers including a dopant selected from the group consisting of erbium and neodymium, and alternating, interposed and laminated with the plurality of group IV nanocrystal material sub-layers;
doping the multilayer material layer to provide a p-i-n diode;
forming over the substrate at least two electrodes, one coupled to each of a p region and an n region within the p-i-n diode.

15. The method of claim 14 wherein:
the forming the multilayer material layer uses radio frequency magnetron sputtering; and
the doping the multilayer material layer uses ion implantation.

16. The method of claim 14 wherein the forming the plurality of group IV nanocrystal material sub-layers is undertaken by thermally annealing a corresponding plurality of group IV amorphous material sub-layers.

17. The method of claim 15 wherein the thermally annealing simultaneously activates a dopant when doping the multilayer material layer when forming the p-i-n diode.

18. The method of claim 14 wherein the plurality of group IV nanocrystal material sub-layers comprises a nanocrystal material selected from the group consisting of silicon, germanium, silicon-germanium alloy, silicon-carbon alloy, germanium carbon alloy and silicon-germanium-carbon alloy nanocrystal materials.

19. The method of claim 14 wherein the plurality of doped dielectric material sub-layers comprises at least one of:
a silicon containing dielectric material selected from the group consisting of silicon oxide, silicon nitride and silicon oxynitride dielectric materials; and
an aluminum oxide dielectric material.

20. The method of claim 14 further comprising forming a dielectric capping layer over the substrate and interposed between the two electrodes.
